(19) United States
(12) Patent Application Publication
(10) Pub. No.: US 2003/0035280 A1
(43) Pub. Date: Feb. 20, 2003

(54) Daughter-card structural support

(76) Inventors: Christopher Gregory Malone, Folsom, CA (US); Stephan Karl Barsun, Auburn, CA (US); Thomas J. Augustin, El Dorado Hills, CA (US)

Correspondence Address: HEWLETT-PACKARD COMPANY, Intellectual Property Administration, P.O. Box 272400, Fort Collins, CO, 80527-2400, US

(21) Appl. No.: 09/932,529

(22) Filed: Aug. 17, 2001

(51) Int. Cl. H05K 7/14

(52) U.S. Cl. 361/796

(57) ABSTRACT

A method and apparatus to provide structural support to one or more daughter-cards attached to a motherboard substrate. One embodiment of the invention involves a method to assemble a daughter-card support to a motherboard. A second embodiment of the invention involves a method to fabricate a daughter-card support. A third embodiment of the invention involves an assembled motherboard substrate with a daughter-card support.

### BACKGROUND OF THE INVENTION

1. Field of the Invention

This invention relates generally to a card stiffener to support a daughter-card substrate, and more specifically relates to a daughter-card support to support a printed circuit board assembly of electronic components.

2. Description of the Prior Art

In many data processing systems (e.g., computer systems, programmable electronic systems, telecommunication switching systems, control systems, and so forth) electrical components (e.g., memory chips, application specific integrated circuits, and processor chips) are assembled on substrates (e.g., printed circuit boards, other flexible substrates, multi-chip modules, and equivalents). Computer manufacturers have been increasing the power, size and quantity of chips attached to printed circuit boards (PCBs). This increase in speed and size has also brought forth an increase in size in related parts, in this case the daughter-card PCB. Furthermore, experience has shown that a long and narrow daughter-card PCB tends to bow in the middle when subject to gravity or external loading (bending due to outside forces). These circumstances lead to the need for some sort of device that reduces/eliminates the bowing seen on long and narrow daughter-cards loaded with heavier processors and associated equipment (i.e., a device that supplies extra structural rigidity to the daughter-card).

The need for closely packing the electrical components also frequently makes it necessary to attach substrates (typically called daughter-cards) slightly above or below larger substrates (typically called mother boards or mother cards). These daughter-cards are conventionally supported above or below the plane of a motherboard by a group of four standoffs (e.g., posts), in order to maintain an air gap between the motherboard and the daughter-card. These standoffs are typically somewhat slender and do not provide much structural rigidity to support the daughter-cards. Furthermore, conventional replacement or removal of a daughter-card requires that the standoffs be disconnected from the daughter-card or the mother board, which may not allow the daughter-cards to be replaced, inserted, or extracted from the mother board.

FIG. 1 illustrates a conventional group of standoffs 102 supporting a daughter-card (e.g., a printed circuit board) 104 above a motherboard 106. The conventional group of standoffs 102 is not designed to provide flatness and rigidity to the daughter-card 104. Furthermore, the conventional group of standoffs may be so closely placed to electrical components 108 on the motherboard 106, that it can be quite difficult to disconnect the standoffs 102 in order to remove and replace the daughter-card 104.

It would be desirable to provide a daughter-card support that allows easier replacement of the daughter-cards, distributes the necessary amount of air-flow to each substrate, and provides the necessary amount of mechanical support to the daughter-card and motherboard substrates.

### SUMMARY OF THE INVENTION

The present invention provides a daughter-card support that allows easier replacement of the daughter-cards, distributes the necessary amount of air-flow to each substrate, and provides the necessary amount of mechanical support to the daughter-card and motherboard substrates.

A first aspect of the invention is directed to a method to assemble a daughter-card support to a motherboard substrate. The method includes assembling one or more electrical components on the motherboard substrate; assembling one or more electrical components on each of one or more daughter-card substrates; attaching the daughter-card support to the motherboard substrate; and attaching the one or more daughter-card substrates to the daughter-card support, wherein the daughter-card support maintains each of the one or more daughter-cards in a fixed position relative to the motherboard substrate.

A second aspect of the invention is directed to a method to fabricate a daughter-card support. The method includes selecting a set of physical dimensions of the daughter-card support; modeling the daughter-card support after insertion of a daughter-card substrate; estimating a more precise set of physical dimensions for the daughter-card support after modeling the daughter-card support with an inserted daughter-card substrate; and shaping the daughter-card support according to the more precise set of physical dimensions.

A third aspect of the invention is directed to an assembled substrate. The assembled substrate includes a motherboard substrate, including one or more electrical components; one or more daughter-card substrates, wherein at least one of the daughter-card substrates includes one or more electrical components; and a daughter-card support to structurally support the one or more daughter-card substrates in fixed orientations relative to the motherboard substrate.

These and other objects and advantages of the invention will become apparent to those skilled in the art from the following detailed description of the invention and the accompanying drawings.

### BRIEF DESCRIPTION OF THE DRAWINGS

FIG. 1 illustrates a conventional group of standoffs supporting a daughter-card (e.g., a printed circuit board) above a motherboard.

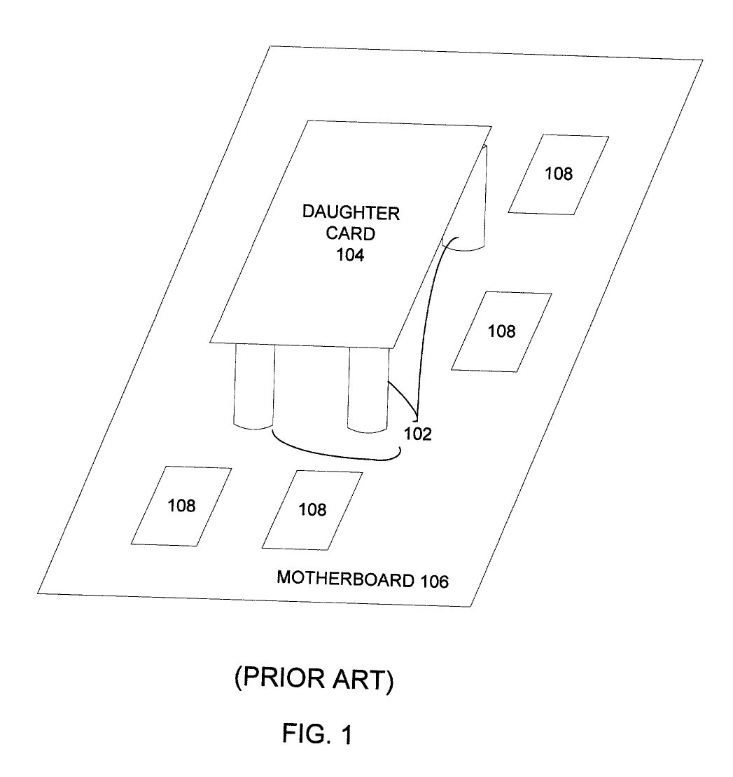

FIG. 2 illustrates one embodiment of a daughter-card support after insertion of a daughter-card substrate (e.g., a PCB) into the daughter-card support, in accordance with one embodiment of the present invention.

FIG. 3 illustrates a daughter-card support with a “spine and rib” style of architecture, in accordance with one embodiment of the present invention.

FIG. 4 illustrates a daughter-card support with a more preferred “circumferential” style of architecture, in accordance with a more preferred embodiment of the present invention.

FIG. 5 shows one flow chart for a method to assemble a daughter-card support to a motherboard substrate in accordance with one embodiment of the present invention.

FIG. 6 shows a flow chart for a method to fabricate a daughter-card support in accordance with one preferred embodiment of the present invention.

### DETAILED DESCRIPTION OF PREFERRED EMBODIMENTS OF THE INVENTION

The present invention provides a daughter-card support that supports a daughter-card substrate, such as a printed circuit board (PCB) or multi-chip module. While the discussion below is directed to an application of the invention to a PCB, the invention can also be applied to other types of electrical components assembled on a substrate (e.g., multi-chip modules, and other substrates upon which electrical components can be assembled). Daughter-card substrates can be held in various planar orientations (e.g., at an acute angle, parallel, or perpendicular to the plane of the motherboard) by a daughter-card support.

In preferred embodiments, a daughter-card support supplies structural rigidity to maintain the separation between one or more daughter-cards and the motherboard, and provides a structure for easier replacement of each daughter-card. In alternative preferred embodiments, the daughter-card support also provides structural rigidity to the motherboard itself. Alternate embodiments of a daughter-card support provide cabling or insertion sockets to maintain proper electrical connections between one or more daughter-cards and the motherboard.

Other preferred embodiments of the daughter-card support also provide air-flow redirection for cooling the daughter-card or the mother board, as needed, by incorporating a plurality of air-flow channels, where each air-flow channel includes one or more holes. Without a proper distribution of air-flow, the heat dissipated from the electrical components can ultimately raise the temperature of the substrates of the daughter-cards or mother board, and cause either permanent or an intermittent failures in the operation of the data processing system. Therefore, it would be desirable to provide redirection of air-flow between the daughter-cards and the mother board to provide sufficient air-flow to cool each daughter-card and mother board substrate.

Daughter-card supports can be fabricated from a sheet metal plate (e.g., a stainless steel alloy, a magnesium alloy, an aluminum alloy), a plastic, a glass-filled plastic, or a composite (e.g., a thermo-set composite material such as a graphite fiber epoxy composite). A daughter-card support is normally constrained in thickness and dimensions by the relatively small separations between nearby motherboard substrates. However, daughter-card supports that are too thin in a physical dimension may distort and fail to adequately support the daughter-card substrates, unless the material is sufficiently rigid to support the weight of the daughter-cards.

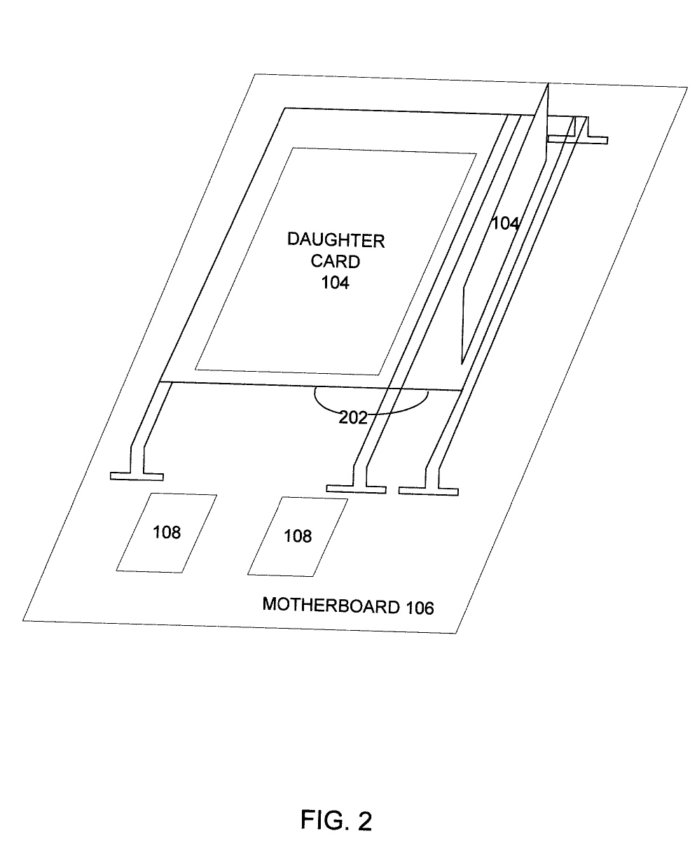

FIG. 2 illustrates one embodiment of a daughter-card support 202 on a motherboard substrate 106 after insertion of daughter-card substrates (e.g., PCBs) 104 into the daughter-card support 202, in accordance with one embodiment of the present invention. The daughter-card support 202 is designed for easier daughter-card replacement, and to provide mechanical support to the daughter-card substrate 104. In preferred embodiments, the daughter-card support 202 holds daughter-card substrates 104 with identical or various planar orientations (e.g., substantially parallel or perpendicular to the plane of the motherboard substrate 106). In alternate embodiments of the invention, the daughter-card support 202 also provides a controlled air-flow distribution between one or more daughter-card substrates 104 and the motherboard substrate 106.

The daughter-card support 202 can be fabricated from the following materials: a stainless steel alloy, a titanium steel alloy, a carbon steel alloy, a magnesium alloy, an aluminum alloy, a plastic, or a composite. One preferred embodiment of the invention has a daughter-card support fabricated from a stainless steel alloy. Stainless steel is corrosion resistant and would not require plating or painting after stamping. Stainless steel also has sufficient strength and stiffness to allow for shape stamping and not require post-stamping heat treatment. This avoids the inherent warpage and distortion associated with heat-treating.

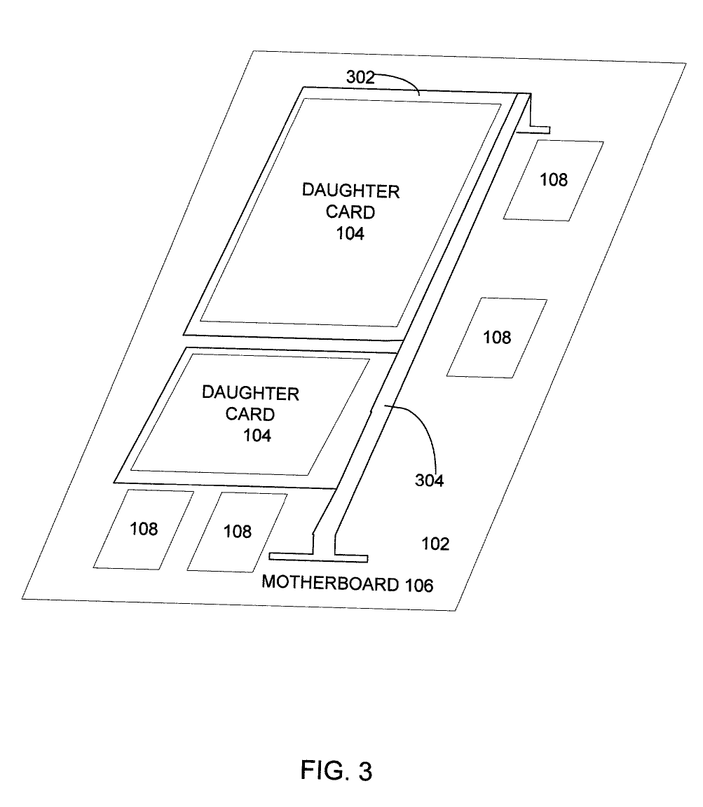

FIG. 3 illustrates a daughter-card support with a “spine and rib” style of architecture, in accordance with one embodiment of the present invention. The ribs 302 and spine 304 are preferably fabricated from stamping a piece of sheet metal or from molding a piece of metal, plastic, or composite. The spine 304 may optionally run the full length of the motherboard substrate 106 with electrical components 108, while the ribs 302 preferably include L-shaped brackets that project perpendicularly from the spine 304 to surround the edges of the daughter-cards 104.

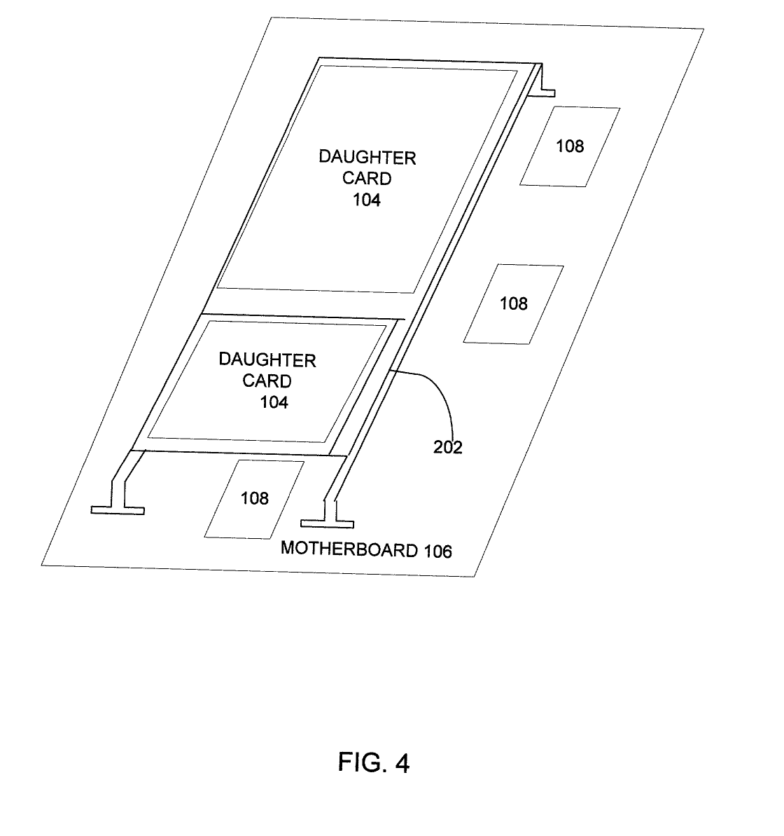

FIG. 4 illustrates a daughter-card support 202 with a more preferred “circumferential” style of architecture, in accordance with a more preferred embodiment of the present invention. In this embodiment of the invention, the daughter-card support 202 is a rectangular structure without a central “spine” and without projecting perpendicular “ribs.” In some preferred embodiments, the daughter-card support 202 has L-shaped brackets to surround the card edges of each daughter-card.

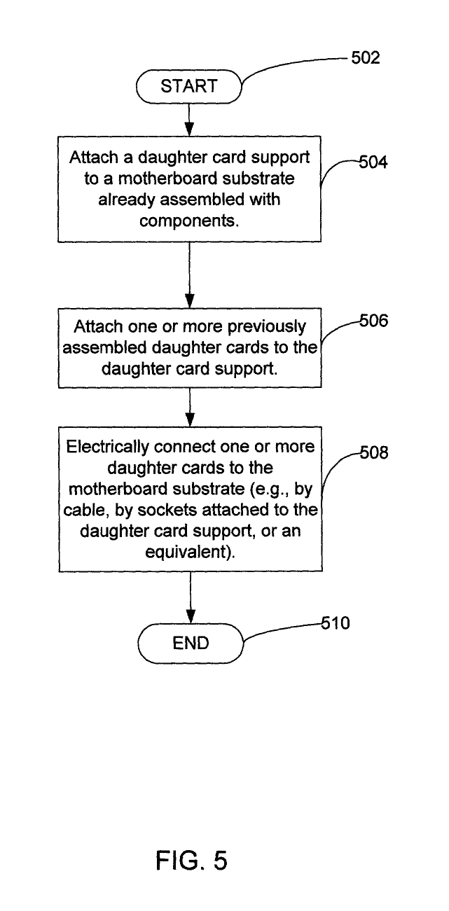

FIG. 5 shows one flow chart for a method to assemble a daughter-card support to a motherboard substrate in accordance with one embodiment of the present invention. The method starts in operation 502, and is followed by operation 504. In operation 504, a daughter-card support is attached to a previously assembled motherboard substrate to support one or more daughter-cards in a plane above or below the plane of a motherboard substrate. The daughter-cards are normally parallel to the plane of the motherboard substrate, but could be perpendicular or at an acute angle to the plane of the motherboard substrate. The daughter-cards are typically on the component side of the motherboard substrate, but could be on the pin side or both sides of the motherboard substrate. Operation 506 is next, where one or more previously assembled daughter-cards are attached to the daughter-card support. Operation 508 is next, where the daughter-cards are electrically connected to the motherboard substrate. Operation 510 is the end of the method.

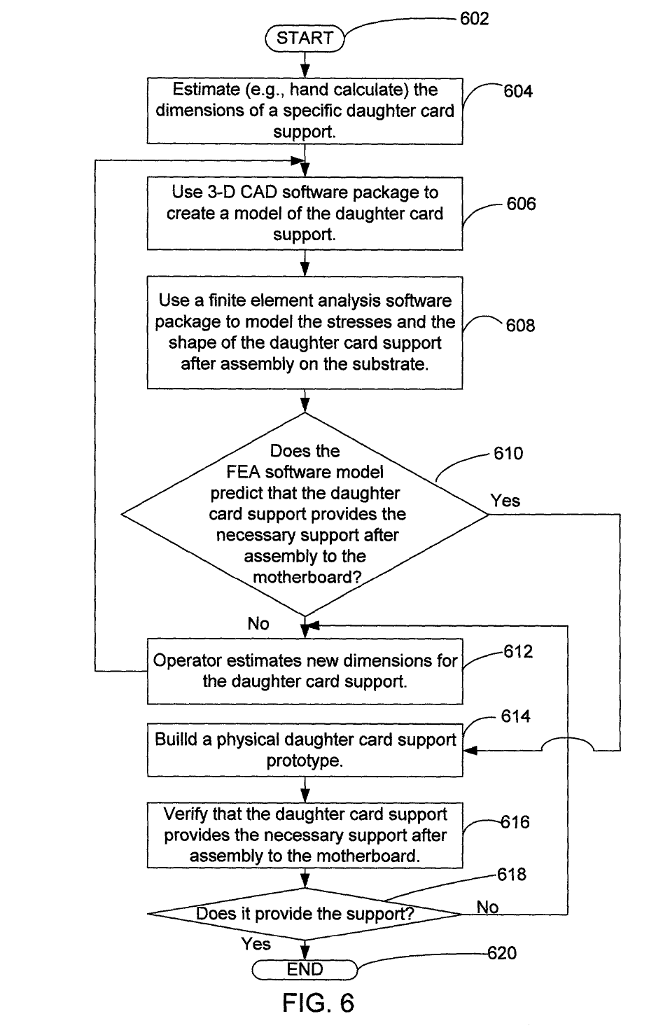

FIG. 6 shows a flow chart for a method to fabricate a daughter-card support in accordance with one preferred embodiment of the present invention. The method starts in operation 602, and is followed by operation 604. In operation 604, a hand calculation is made of the necessary daughter-card support rigidity and air-flow balancing needed for the assembled motherboard and one or more daughter-cards. In operation 606, a 3-D computer aided design (CAD) software package (e.g., Pro/ENGINEER, available from PTC Corporation with corporate headquarters in Needham, Mass.; SolidDesigner, available from CoCreate Software, Inc. with corporate headquarters in Fort Collins, Colo.; SolidWorks, available from SolidWorks Corporation with corporate headquarters in Concord, Mass.; or an equivalent CAD package) is used to create a model of the daughter-card support assuming the previously estimated dimensions. Then operation 608 is next. In operation 608, a finite element analysis (FEA) software package (e.g., Pro/MECHANICA, available from PTC Corporation with corporate headquarters in Needham, Mass.; Ansys, available from Ansys, Inc. with corporate headquarters in Canonsburg, Pa.; Cosmos, available from Structural Research & Analysis Corporation with corporate headquarters in Los Angeles, Calif.; or an equivalent FEA package) is used to model the stresses and the predict the final shape of the daughter-card support after assembly of the daughter-card support to the motherboard. In operation 610, a test is made to determine if the FEA software package predicts that that the daughter-card support provides sufficient daughter-card and motherboard support, and (optionally) a sufficient air-flow after insertion of all the daughter-cards into the daughter-card support. If the test of operation 610 determines that the daughter-card support will not provide sufficient daughter-card and motherboard support, or (optionally) not provide sufficiently distributed air-flow, operation 612 is next where the operator decides on new dimensions. Then operations 606, 608, and 610 are repeated. If the test of the operation 610 determines that the daughter-card support will provide sufficient daughter-card and motherboard support, and (in alternative preferred embodiments) an air-flow redistribution, then operation 614 is next. In operation 614 a physical daughter-card support prototype is fabricated. Operation 616 is next, where fully operational daughter-cards are attached to the daughter-card support, which is connected to the motherboard to verify that the daughter-card support will satisfy all structural, electrical, and thermal requirements for reliable operation. Then operation 618 is next, where a test is made to determine if the daughter-card support satisfies all the physical and operational requirements. If the test of operation 618 verifies that daughter-card support does not satisfy all requirements, then operation 612 is next. If the test of operation 618 verifies that the daughter-card support satisfies all requirements, then the method ends in operation 620.

In an alternative preferred embodiment, the daughter-card support includes two-halves to “clamshell” the daughter-card PCB between the daughter-card support. In a more preferred embodiment, one-half of the daughter-card support is placed on a planar surface (e.g., a table), and the daughter-card PCB is aligned and placed via alignment pins in the daughter-card support. The second half of the daughter-card support is placed on the daughter-card PCB, aligned with the same alignment pins that exist on the first half of the daughter-card support, and fasteners (e.g., bolts, or screws) are placed through holes in the top and the bottom of the daughter-card support to effectively contain and support the daughter-card and motherboard.

In another preferred embodiment, the daughter-card support also acts as a platform for assembly or repairs of the daughter-card or motherboard. Optional “legs” support the daughter-card or motherboard off of a working surface. The daughter-card support is formed in such a way that it can optionally support a power supply, a processor, and/or an integral heat sink. The structure can be four-sided, two-sided (support a daughter-card at opposite card edges), or include a “spine and ribs” flying support (i.e., the daughter-card support rises above the motherboard).

The embodiments of the invention discussed above mainly described examples of daughter-card and motherboard substrates assembled with IC components. However, alternative embodiments of the invention can be applied to substrates holding other components (e.g., IC components, transformers, power supplies, connectors, or other devices that can cause daughter-card or motherboard substrate distortion by an attachment force, or from the weight of the component).

The exemplary embodiments described herein are for purposes of illustration and are not intended to be limiting. Therefore, those skilled in the art will recognize that other embodiments could be practiced without departing from the scope and spirit of the claims set forth below.

What is claimed is:

1. A method to assemble a daughter-card support to a motherboard substrate, comprising:
assembling one or more electrical components on said motherboard substrate;
assembling one or more electrical components on each of one or more daughter-card substrates;
attaching said daughter-card support to said motherboard substrate; and
attaching said one or more daughter-card substrates to said daughter-card support, wherein said daughter-card support maintains each of said one or more daughter-cards in a fixed position relative to said motherboard substrate.

2. The method of claim 1, wherein said motherboard substrate and said one or more daughter-card substrates are selected from the group of substrates consisting of: a printed circuit board (PCB), a multi-chip module (MCM), and a flexible substrate.

3. The method of claim 1, wherein said daughter-card support further comprises one or more electrical connections to a daughter-card substrate.

4. The method of claim 1, wherein said daughter-card support is fabricated from a material selected from the group of materials consisting of: a stainless steel alloy, a magnesium alloy, an aluminum alloy, a plastic, or a composite.

5. The method of claim 1, wherein said daughter-card support has a “spine and rib” style of architecture.

6. The method of claim 1, wherein said daughter-card support has one or more L-shaped brackets to hold one or more card edges of said one or more daughter-cards.

7. The method of claim 1, wherein said daughter-card support allows hand replacement of one or more daughter-card substrates.

8. A method to fabricate a daughter-card support, comprising:
selecting a set of physical dimensions of said daughter-card support;
modeling said daughter-card support after insertion of a daughter-card substrate;
estimating a more precise set of physical dimensions for said daughter-card support after modeling said daughter-card support with an inserted daughter-card substrate; and
shaping said daughter-card support according to said more precise set of physical dimensions.

9. The method of claim 8, wherein said motherboard substrate and said one or more daughter-card substrates are selected from the group of substrates consisting of: a printed circuit board (PCB), a multi-chip module (MCM), and a flexible substrate.

10. The method of claim 8, wherein said daughter-card support further comprises one or more electrical connections to a daughter-card.

11. The method of claim 8, wherein said daughter-card support is fabricated from a material selected from the group of materials consisting of: a stainless steel alloy, a magnesium alloy, an aluminum alloy, a plastic, or a composite.

12. The method of claim 8, wherein said daughter-card support has one or more L-shaped brackets to hold one or more card edges of said one or more daughter-cards.

13. An assembled substrate, comprising:
a motherboard substrate, including one or more electrical components;
one or more daughter-card substrates, wherein at least one of said daughter-card substrates includes one or more electrical components; and
a daughter-card support to structurally support said one or more daughter-card substrates in fixed orientations relative to said motherboard substrate.

14. The assembled substrate of claim 13, wherein said motherboard substrate and said one or more daughter-card substrates are selected from the group of substrates consisting of: a printed circuit board (PCB), a multi-chip module (MCM), and a flexible substrate.

15. The assembled substrate of claim 13, wherein said daughter-card support further comprises one or more electrical connections to a daughter-card.

16. The assembled substrate of claim 13, wherein said daughter-card support is fabricated from a material selected from the group of materials consisting of: a stainless steel alloy, a magnesium alloy, an aluminum alloy, a plastic, or a composite.

17. The assembled substrate of claim 13, wherein said daughter-card support has a “spine and rib” style of architecture.

18. The assembled substrate of claim 13, wherein said daughter-card support has one or more L-shaped brackets to hold one or more card edges of said one or more daughter-cards.

19. The assembled substrate of claim 13, wherein said daughter-card support allows hand replacement of one or more daughter-card substrates.

20. The assembled substrate of claim 13, wherein said daughter-card support has a plurality of air-flow channels, wherein each air-flow channel includes one or more holes.
